(19) United States
(12) Patent Application Publication
(10) Pub. No.: US 2003/0160562 A1
(43) Pub. Date: Aug. 28, 2003

(54) Electroluminescent display device

(76) Inventors: Mitsuoki Hishida, Kaidu-gun (JP); Yoshitaka Nishio, Osaka (JP); Hiroshi Matsuki, Hashima-gun (JP)

Correspondence Address: Barry E. Bretschneider, Morrison & Foerster LLP, Suite 300, 1650 Tysons Boulevard, McLean, VA, 22102, US

(21) Appl. No.: 10/372,812

(22) Filed: Feb. 26, 2003

(30) Foreign Application Priority Data
Feb. 26, 2002 (JP) 2002-049611

(51) Int. Cl. H01J 1/62; H05B 33/00

(52) U.S. Cl. 313/498

(57) ABSTRACT

The invention provides an electroluminescent display device that includes a substrate, a first electrode disposed above the substrate and a second electrode disposed above the first electrode. The device also includes an electroluminescent element disposed between the first and second electrodes, and a thin-film transistor driving the electroluminescent element. The electroluminescent element includes a light emitting layer. The second electrode is made of aluminum and has a thickness between 2000 Å and 10000 Å. Although defects may be formed during the initial formation of the second electrode, these defects are filled up by aluminum until the metal is deposited to a predetermined thickness.

### BACKGROUND OF THE INVENTION

1. Field of the Invention

This invention relates to an electroluminescent (EL) display device, specifically to an EL display device free from processing flaws.

2. Description of the Prior Arts

In recent years, EL display devices using EL elements have come to be known as display devices that can replace CRT and LCD. Research and development have been carried out on active matrix type EL display devices that include thin film transistors (TFT) as switching elements for driving EL elements. The EL element includes an anode, a cathode and a light emitting layer disposed between the anode and cathode. However, the cathode, which is formed on the light emitting layer, is known to be prone to defect formation.

### SUMMARY OF THE INVENTION

The invention provides an electroluminescent display device that includes a substrate, a first electrode disposed above the substrate and a second electrode disposed above the first electrode. The thickness of the second electrode is at least 2000 Å. The device also includes an electroluminescent element disposed between the first and second electrodes, which includes a light emitting layer.

### BRIEF DESCRIPTION OF THE DRAWINGS

FIG. 1 is a plan view of an EL display device of an embodiment of this invention.

FIG. 2 is an equivalent circuit diagram of the device of FIG. 1.

FIG. 3A is a cross-sectional view of the device of FIG. 1 cut along line A-A shown in FIG. 1, and FIG. 3B is another cross-sectional view of the device of FIG. 1 cut along line B-B shown in FIG. 1.

FIG. 4A shows the formation of dark spots in the EL display device with a 4000 Å thick cathode of the embodiment of this invention, and FIG. 4B shows the formation of dark spots in the EL display device with a 1000 Å thick cathode.

FIG. 5, shows the number of dark spots formed in the EL display device as a function of the thickness of the aluminum cathode layer.

FIG. 6 schematically shows the defect formation in the aluminum cathode layer.

### DETAILED DESCRIPTION OF THE INVENTION

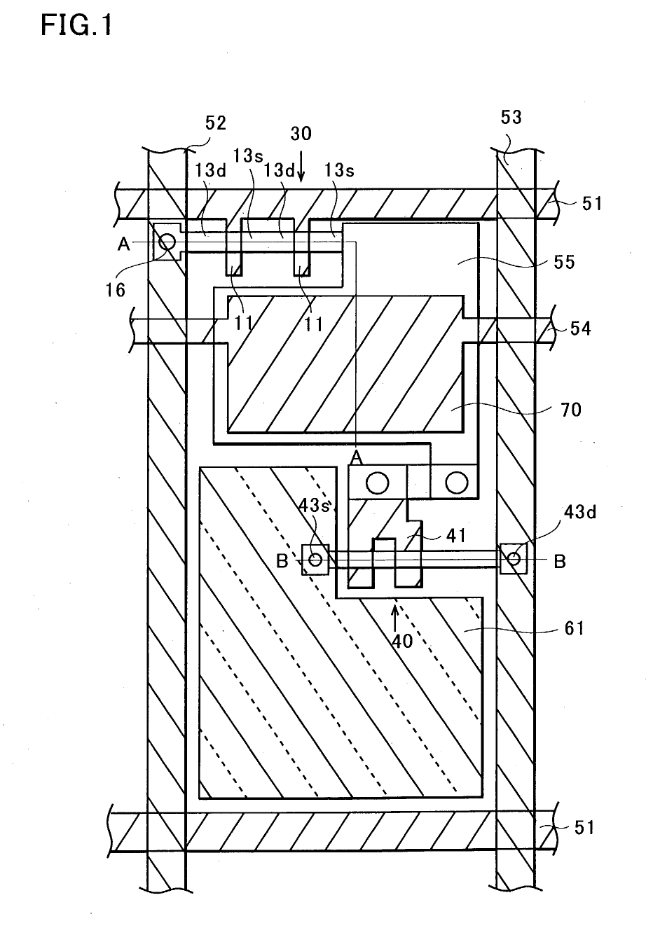

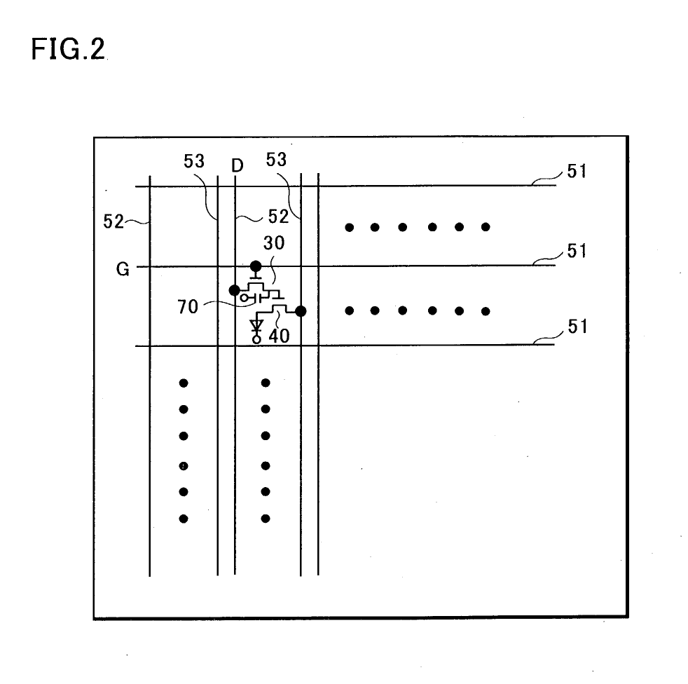

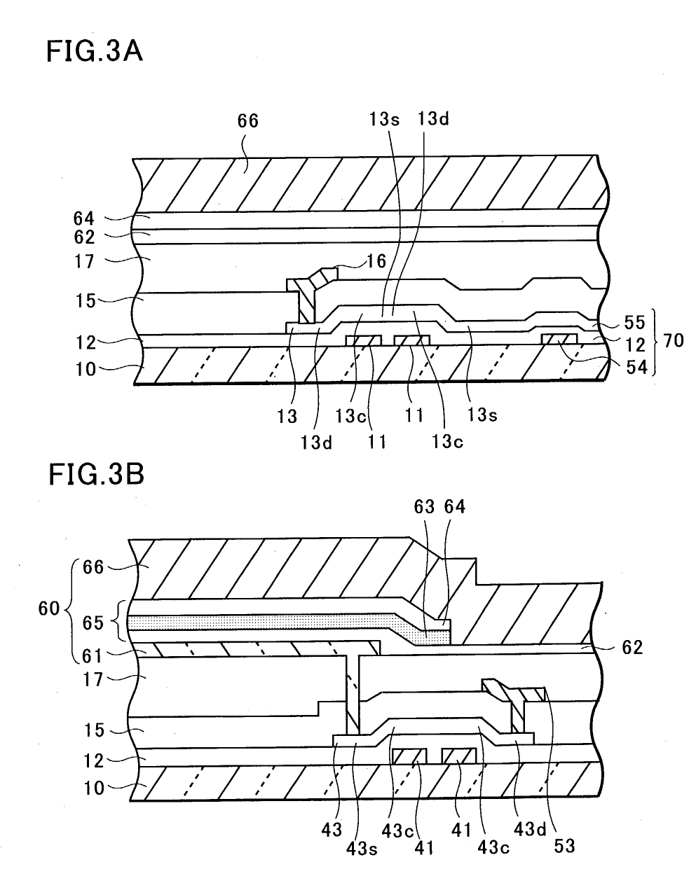

An embodiment of this invention will be described with reference to FIGS. 1-6. FIG. 1 is a plan view of one of the display pixels of an organic EL display device of this embodiment. FIG. 2 is an equivalent circuit diagram of the display pixel of FIG. 1. As shown in FIG. 2, the display pixels of the same configuration shown in FIG. 1 are arranged in a matrix to form the device. FIG. 3A is a sectional view along line A-A in FIG. 1, and FIG. 3B is a sectional view along line B-B in FIG. 1.

As shown in FIGS. 1 and 2, a display pixel is formed in a region surrounded by gate signal lines 51 and drain signal lines 52. A first TFT 30, which is a switching element, is located near an intersection of the signal lines, and a source 13s of this TFT 30 serves at the same time as a capacitor electrode 55 that forms a capacitor in combination with a holding capacitor electrode 54 and is connected to a gate electrode 41 of a second TFT 40 that drives an organic EL element. A source 43s of second TFT 40 is connected to an anode 61 of the organic EL element and a drain 43d is connected to a driving power supply line 53 for driving the organic EL element.

A holding capacitor electrode 54, which runs parallel to gate signal line 51, is positioned near the TFTs. This holding capacitor electrode 54 is formed of chromium or the like, and accumulates charges to form a capacitor across a gate insulation film 12 together with the capacitor electrode 55 connected to source 13s of TFT 30. This holding capacitor is provided to hold a voltage that is applied to the gate electrode 41 of second TFT 40.

First TFT 30, which is the switching TFT, will be described.

As shown in FIG. 3A, the gate signal lines 51, which also serve as gate electrodes 11, and the holding capacitor electrode line 54 are made of a high-melting-point metal, such as chromium (Cr) and molybdenum (Mo), and formed on an insulating substrate 10, formed of quartz glass, non-alkaline glass or the like.

The gate insulation film 12 and an active layer 13, formed of a polycrystalline silicon (p-Si) film, are formed in this order. The active layer 13 includes channels 13c, which overlaps with the gate electrode, and the sources 13s and the drains 13d, which are provided at both ends of each of the channels 13c. The active layer 13 may be of a LDD (Lightly Doped Drain) structure. In this structure, the channel 13c is sandwiched between low impurity regions, and the low impurity regions are further bordered with high impurity regions.

An interlayer insulation film 15, formed by laminating an SiO₂ film, an SiN film, and an SiO₂ film, in this order, is provided across the entire surface above the gate insulation film 12 and the active layer 13, and a drain electrode 16, which also serves as the drain signal line 52, is disposed by filling aluminum or other metal in a contact hole that is provided corresponding to the drain 13d. A planarizing insulation film 17, which is formed, for example, of an organic resin and planarizes the surface, is provided on the entire surface. On top of this are laminated the respective organic materials 62 and 64 of an organic EL element 60 and a cathode 66. A feature of this embodiment is that the cathode has a thickness of about 4000 Å.

Second TFT 40, which is the driving TFT that supplies currents to the organic EL element, will now be described with reference to FIG. 3B.

With second TFT 40, the gate electrodes 41 are made of a high-melting-point metal, such chromium (Cr) and molybdenum (Mo), and formed on an insulating substrate 10, formed of quartz glass, non-alkaline glass or the like. The gate insulation film 12 and an active layer 43, formed of p-Si film, are formed in this order. The active layer 43 includes channels 43c, which is made of intrinsic or substantially intrinsic p-Si, located above the gate electrodes 41. At the respective sides of the channels 43c, ion doping is applied, thereby forming the source 43s and the drain 43d.

The interlayer insulation film 15, formed by lamination of a SiO₂ film, a SiN film, and a SiO₂ film, in this order, is provided across the entire surface above the gate insulation film 12 and the active layer 43, and the driving power supply line 53, which is connected to a driving power supply, is disposed by depositing aluminum or other metal in a contact hole that is provided corresponding to the drain 43d. The planarizing insulation film 17, which is formed, for example, of an organic resin and makes the surface flat, is further provided across the entire surface, a contact hole is formed through positions of the planarizing insulation film 17 and the interlayer insulation film 15 that correspond to the source 43s. A first electrode, that is, the organic EL element's anode 61, which is formed of ITO (indium tin oxide) that contacts the source 43s via the contact hole, is formed on the planarizing insulation film 17.

The organic EL element 60 has a structure formed by laminating the anode 61, made of a transparent electrode of ITO or the like, a light emitting layer 65 and a second electrode, that is, the cathode 66, made of a magnesium/indium alloy. The light emitting element layer 65 includes a hole transport layer 62, which has a first hole layer made of MTDATA (4,4′,4″-tris(3-methylphenylphenylamino)triphenylamine), and a second hole transport layer made of TPD (N,N′-diphenyl-N,N′-di(3-methylphenyl)-1,1′-biphenyl-4,4′-diamine), a light emitting layer 63 made of Bebq2 (bis(10-hydroxybenzo[h]quinolinato)beryllium) that contains quinacridone, and an electron transport layer 64 formed of Bebq2. The cathode 66 is disposed across the entire surface of substrate 10 that forms the organic EL display device shown in FIG. 1, and has a film thickness of 4000 Å.

In the organic EL element, holes injected from the anode and electrons injected from the cathode recombine inside the light emitting layer, thereby exciting organic molecules in the light emitting layer and giving rise to excitons. Light is emitted from the light emitting layer as these excitons undergoes radiative dissipation and this light is discharged to the exterior from the transparent anode and via the transparent insulating substrate, thereby causing luminescence.

The forming of the light emitting layer 63 of the organic EL element will now be described.

The light emitting layer 63 emits light of any of various colors and a different material is provided in accordance with the colors. The materials are deposited on the second hole transport layer by vapor deposition. In this process, light emitting materials of the various colors, for example, red (R), green (G), and blue (B), are deposited successively in insular form on the corresponding anodes 61 to form the matrix configuration of the device.

In vapor depositing the light emitting layer materials of the respective colors, a first color is vapor deposited using a metal mask that is opened in matrix form, and this mask is moved transversely or longitudinally to perform vapor deposition of the respective colors successively. The mask may be made of tungsten, silicon or the like.

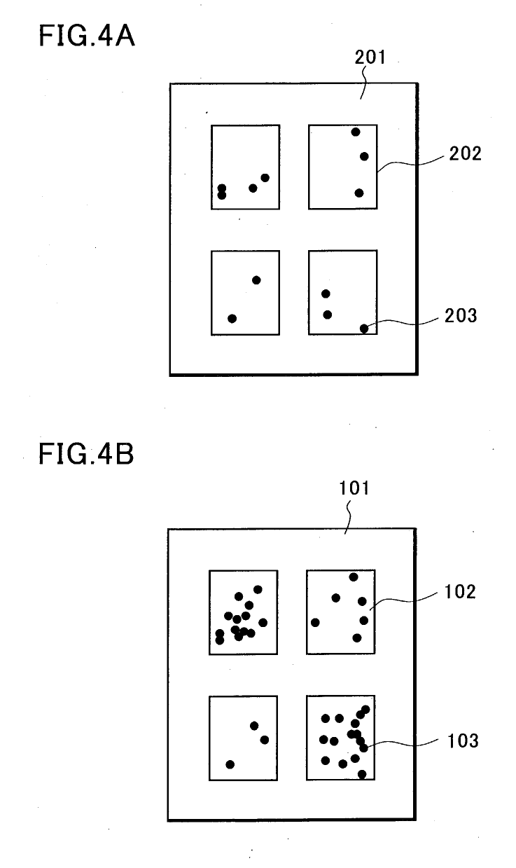

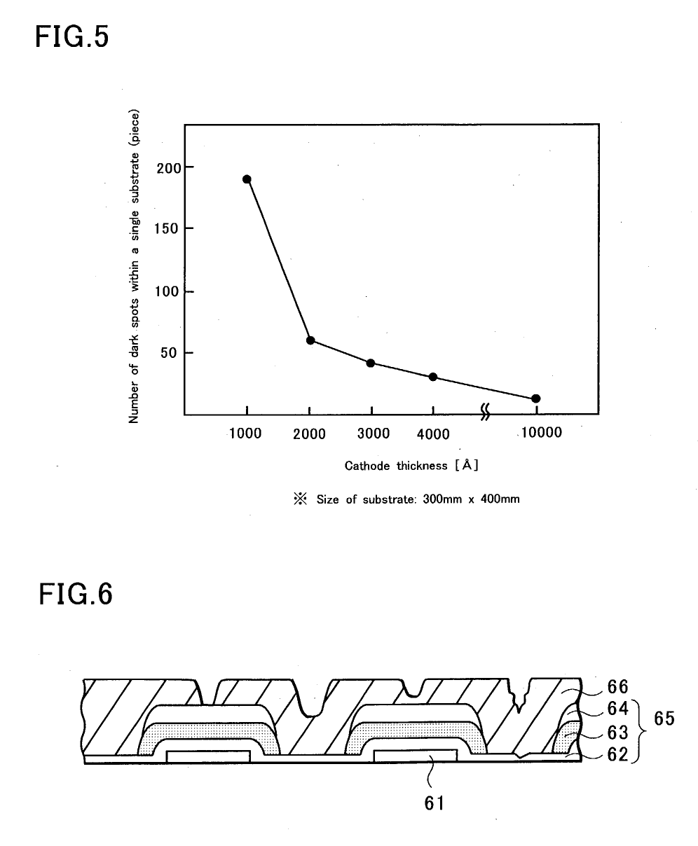

The effects of this invention will now be described with reference to FIGS. 4A, 4B and 5. Dark spots in the display area are known to result from defect formation in the aluminum cathode 66. The inventors performed an experiment in which the thickness of the cathode was varied while keeping the rest of the structure of the display device the same as described above to evaluate the effect of the cathode thickness on the dark spot formation.

FIG. 4A shows the dark sports that appeared in the display device of this embodiment, which has a cathode thickness of 4000 Å. As an example, four display panels 202 of the display device of this embodiment are mounted on a mother glass 201 for observation. FIG. 4B shows the dark spots that appeared in a display device that had the same structure as the display device of this embodiment except that the thickness of the cathode was 1000 Å. The number of the dark spots of the device with the 4000 Å thick cathode was approximately one fourth of that of the device with the 1000 Å thick cathode.

FIG. 5 shows the number of the dark spots as a function of the thickness of the cathode. All the dark spots within a single mother glass having a size of 300 mm×400 mm were counted for each of the specimens. As shown in FIG. 5, as long as the thickness of the cathode was 2000 Å or greater, the number of the dark spots were small although there was a gradual decrease in the number with increasing cathode thickness. At the cathode thickness of 1000 Å, however, the number of the dark spots drastically increased.

The inventors believe that the following observation will explain the result shown in FIG. 5. First, as shown in FIG. 6, since the aluminum layer, which forms the cathode 66, is formed by vapor deposition, the aluminum layer thus formed has a low density and is prone to defect formation. For example, when a metal mask is moved from one position corresponding to one color to another position corresponding to another color so that light emitting layers corresponding to each color are formed successively, the hole transport layer 62, on which the light emitting layers are formed, may be damaged because of the movement of the mask. If aluminum is vapor deposited on the defective hole transport layer 62, the aluminum layer will also develop a defect based on the defect in the hole transport layer 62, as shown in FIG. 6. A typical example of such a defect is a step or a pinhole. Even when there is no defect in the hole transport layer 62, the defects in the aluminum layer are formed due to dust adsorption on the surface during the film forming process.

When there are defective parts in the aluminum layer of the cathode as shown in FIG. 6, the light emitting element layer 65 below the defective part is exposed to ambient air and moisture enters inside. When moisture enters inside a pixel, not only does that pixel become defective and gives rise to a missing point defect, but the moisture that entered into the pixel also affects neighboring pixels successively, thereby causing dark spots, which are non-luminescent regions, to increase, and eventually, the entire panel may become unable to perform display functions. Such a defect of the aluminum layer can cause the above problem in the light emitting layer even if it is, for example, about 0.3 μm in size. Accordingly, protecting light emitting element layer 65 from ambient air is thus essential.

The manufacturing of conventional EL display devices, in which the thickness of the aluminum cathode layer is approximately 1000 Å, has been known to produce defective products dues to the problems described above. If just the aluminum layer itself is considered, the holes in the aluminum layer might be closed by aluminum reflow process. However, since light emitting element layer 65, which is formed prior to the cathode aluminum layer, is weak against heat treatment, the entire device intermediate cannot be heated. Accordingly, it has been difficult to improve the yield of manufacturing the conventional device.

In this embodiment, however, the aluminum layer forming the cathode 66 has a thickness between 2000 Å and 10000 Å, and thus eliminates the generation of pinholes in the cathode, which might be formed in a thinner aluminum layer due to ultrafine dust during the film forming process or due to defects of the hole transport layer.

This is because, by making the film thickness of the aluminum cathode layer large, the pinholes that are formed in the initial stages of vapor deposition of aluminum are filled with aluminum by the time of completion of vapor deposition.

The aluminum layer and the organic layer below it differ in rigidity. Thus if the aluminum layer becomes too thick, stresses are generated between the aluminum layer and the organic layer, leading to peeling off of the thick film. The aluminum layer thus preferably has a thickness smaller than 10000 Å. In this embodiment, however, an aluminum film having a thickness of 4000 Å has provided an optimal results.

Furthermore, another feature of this embodiment is that the cathode does not only serve as a conductive film but also as a protective layer for the organic film. Since the aluminum layer has an adequate protective capability because of its thickness, the need to further provide a separate protective layer on top of the cathode is eliminated. Although the formation of the thick aluminum film may take some additional processing time in comparison that of the conventional device, the overall processing time of the device may not be different form that of the conventional device.

What is claimed is:

1. An electroluminescent display device comprising:
a substrate;
a first electrode disposed above the substrate;
a second electrode disposed above the first electrode, a thickness of the second electrode being at least 2000 Å; and
an electroluminescent element disposed between the first and second electrodes, the electroluminescent element comprising a light emitting layer.

2. The electroluminescent display device of claim 1, further comprising a thin film transistor that drives the electroluminescent element.

3. The electroluminescent display device of claim 1, wherein the thickness of the second electrode is less than 10000 Å.

4. The electroluminescent display device of claim 1, wherein the second electrode comprises an aluminum layer.

5. The electroluminescent display device of claim 1, wherein the electroluminescent display device is configured to emit light in a direction from the second electrode to the first electrode.

6. The electroluminescent display device of claim 1, wherein the substrate is made of a transparent material.
